(19) United States
(12) Patent Application Publication
(10) Pub. No.: US 2026/0282821 A1
(43) Pub. Date: Sep. 17, 2026

(54) SEMICONDUCTOR PROCESSING SYSTEM AND METHOD FOR OPERATING THE SAME

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Yang SUN, Shanghai City (CN); Rong ZHU, Shanghai City (TW); Wen-Jing HUANG, Shanghai City (CN); Yifeng ZHUANG, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/089,899

(22) Filed: Mar. 25, 2025

(30) Foreign Application Priority Data
Mar. 12, 2025 (CN) 202520435294.4

(51) Int. Cl. H01L 21/677; H01L 21/67

(52) U.S. Cl. CPC H10P 72/3404; H10P 72/0608; H10P 72/3402; H10P 72/3406; H10P 72/3408; H10P 72/3411

(57) ABSTRACT

A method for operating a semiconductor processing system is provided. The method includes performing a semiconductor process by a semiconductor fabrication apparatus, wherein the semiconductor fabrication apparatus comprises a plurality of load ports arranged substantially along a first direction in a top view; moving a stage between a first region and a second region substantially along a second direction intersecting the first direction in the top view, wherein the stage supports a transfer robot, and the first region is nearer to the load ports than the second region is; using the transfer robot, transferring a wafer carrier between a stocker apparatus and a semiconductor fabrication apparatus when the stage is at the first region; and performing a maintenance process to the semiconductor fabrication apparatus when the stage is at the second region.

### PRIORITY CLAIM AND CROSS-REFERENCE

The present application claims priority to China Application Serial Number 202520435294.4, filed Mar. 12, 2025, which is herein incorporated by reference.

### BACKGROUND

Generally, the semiconductor manufacturing industry involves highly complex techniques for fabricating integrating circuits using semiconductor materials, which are layered and patterned onto a substrate, such as silicon. An integrated circuit is fabricated from reticles. Initially, circuit designers provide circuit pattern data, which describes a particular integrated circuit (IC) design, to a reticle production system, which transforms the pattern data into reticles. Due to the large scale of circuit integration and the decreasing size of semiconductor devices, the reticles and fabricated devices have become increasingly sensitive to defects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a semiconductor processing system according to some embodiments of the present disclosure.

FIG. 1B is a schematic view of a moving mechanism of a carrier transferring assembly in the semiconductor processing system of FIG. 1A.

FIG. 1C is a side view of a semiconductor fabrication apparatus in the semiconductor processing system of FIG. 1A.

FIGS. 2A and 2B are flow charts of a method for operating a semiconductor processing system according to some embodiments of the present disclosure.

FIGS. 3-13 are top views of a semiconductor processing system at operating various stages according to some embodiments of the present disclosure.

FIG. 14 shows pulses versus time for various processes when operating the semiconductor processing system according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

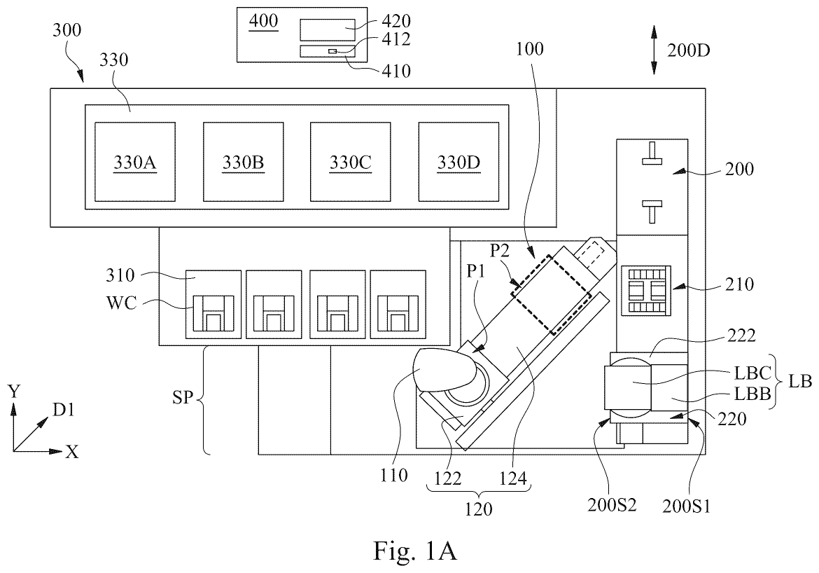

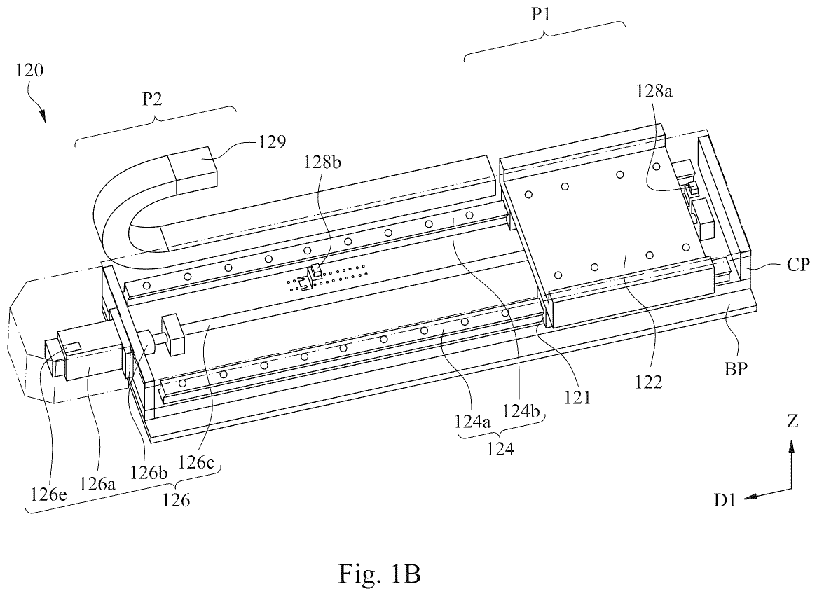

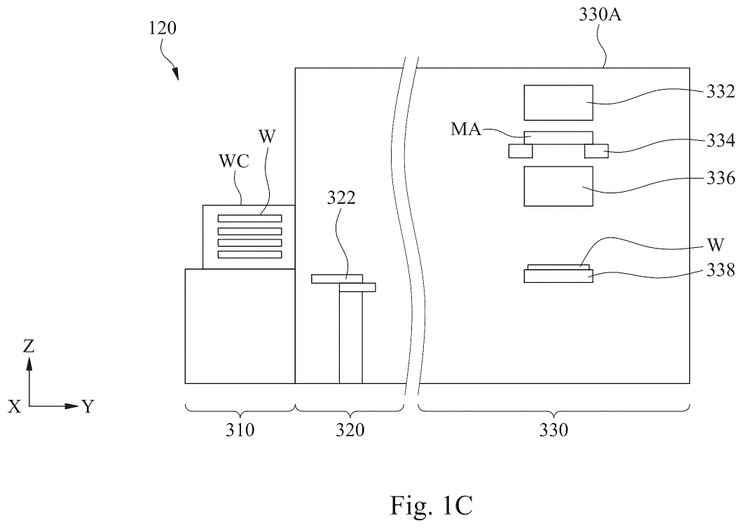

FIG. 1A is a top view of a semiconductor processing system according to some embodiments of the present disclosure. The semiconductor processing system include a carrier transferring assembly 100, a stocker apparatus 200, a semiconductor fabrication apparatus 300, and a control system 400. The carrier transferring assembly 100 is a fully automatic transportation system that transfers a wafer carrier WC between the stocker apparatus 200 and the semiconductor fabrication apparatus 300. The wafer carrier WC may include a wafer cassette, a front-opening unified pod (FOUP), a pod, a container, or a similar type of device configured to hold and/or store plural wafers W.

The carrier transferring assembly 100 may include a transfer robot 110 and an auto moving mechanism 120 supporting the transfer robot 110. The transfer robot 110 has a range of motion sufficient to transfer the wafer carrier WC between the semiconductor fabrication apparatus 300 and the stocker apparatus 200. For example, the transfer robot 110 is configured to move the wafer carrier WC from the stocker apparatus 200 to the semiconductor fabrication apparatus 300 and move the wafer carrier WC from the semiconductor fabrication apparatus 300 to the stocker apparatus 200. The moving mechanism 120 includes a stage 122 supporting the transfer robot 110 and a rail assembly 124. The rail assembly 124 may be a linear guide extending along a direction D1, and the stage 122 can be moved on the rail assembly 124 along the direction D1. In some embodiments of the present disclosure, the stage 122 is at a first region P1 during a carrier transferring process and at a second region P2 during a maintenance process. The first region P1 is nearer load ports 310 of the semiconductor fabrication apparatus 300 than the second region P2. For example, a minimal distance (or a shortest distance) from the first region P1 to the load ports 310 is less than a minimal distance (or a shortest distance) from the second region P2 to the load ports 310.

In some embodiments of the present embodiments, the first region P1 is aligned with an empty space/area in front of the load ports 310 of the semiconductor fabrication apparatus 300 along the direction X. And, the second region P2 may be aligned with the load ports 310 of the semiconductor fabrication apparatus 300 along the direction X. In the context, the first region P1 may be referred to as a working region, and the second region P2 may be referred as a non-working region.

The stocker apparatus 200 is an automatic system for handling a wafer box LB. The wafer box LB is configured to accommodate the wafer carrier WC, and can be moved manually or automatically. For example, the wafer box LB has a body LBB accommodating the wafer carrier WC and a cover LBC covering the opening of the body. In some embodiments, the stocker apparatus 200 has a first station 210 for receiving a wafer box LB and a second station 220 for opening/closing the wafer box LB. The first station 210 may be referred to as a storage station. The second station 220 may be referred to as an opening/closing station. For example, a box opening device 222 at the second station 220 can rotate the cover LBC, thereby moving the cover LBC away from the body LBB to expose the interior of the body LBB or moving the cover LBC back to the body LBB to cover the body LBB.

In some embodiments, the stocker apparatus 200 has an elongated shaped extending along a direction 200D, and the stocker apparatus 200 has opposite two sides 200S1 and 200S2 extending along the direction 200D. In some embodiments, the two sides 200S1 and 200S2 of the stocker apparatus 200 are used for manual transportation and auto transportation, respectively. For example, an operator at the side 200S1 can manually move the wafer box LB to the first station 210. In some embodiments, the transfer robot 110 or transfer components of the stocker apparatus 200 may move the wafer box LB from the first station 210 to the second station 220. The box opening device 222 at the second station can open the wafer box LB to release the wafer carrier WC in the wafer box LB. Subsequently, a transfer robot 110 of the carrier transferring assembly 100 at the side 200S2 can automatically move the wafer carrier WC from the second station 220 to the semiconductor fabrication apparatus 300.

The semiconductor fabrication apparatus 300 includes one or more load ports 310 and a semiconductor processing tool 330. The load ports 310 may be configured to receive wafer carriers WC from the transfer robot 110 of the carrier transferring assembly 100 and support the wafer carriers WC. The semiconductor processing tool 330 may include one or more tools 330A-330D configured to perform one or more semiconductor processes on one or more semiconductor substrates and/or devices. For example, the semiconductor processing tool 330 may include an exposure tool 330A (e.g., an extreme ultraviolet (EUV) tool, an electron beam (e-beam) tool), a deposition tool 330B (e.g., a tool configured to deposit one or more layers onto a semiconductor substrate), an etch tool 330C (e.g., a wet etch tool, a dry etch tool), a baking tool 330D, or another type of semiconductor processing tool.

The control system 400 may control various operations of the carrier transferring assembly 100, the stocker apparatus 200, and the semiconductor fabrication apparatus 300 for performing the carrier transferring process and the maintenance process. For example, the control system 400 may control the carrier transferring assembly 100 to move the stage 122 to the first region P1 for the carrier transferring process, and control the carrier transferring assembly 100 to move the stage 122 to the second region P2 for the carrier transferring process.

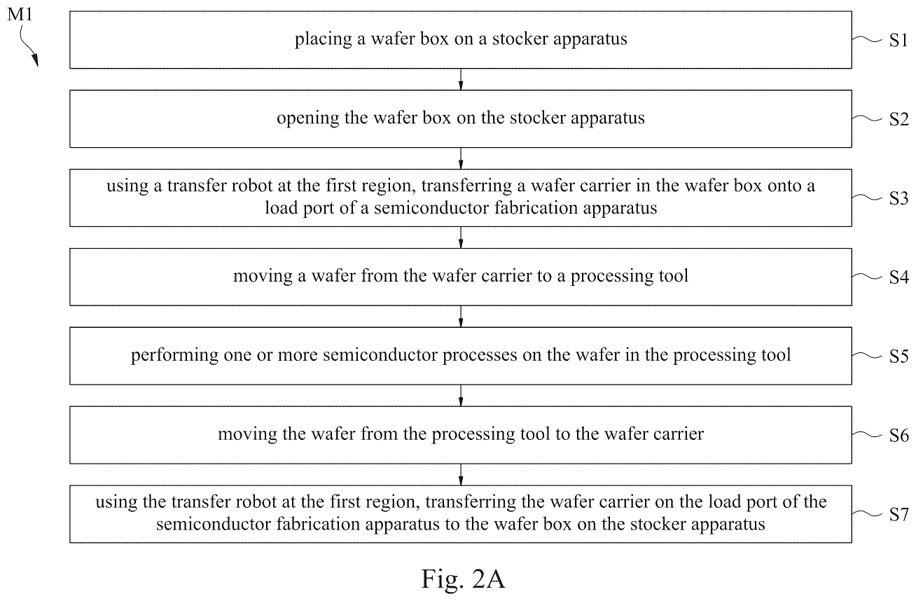

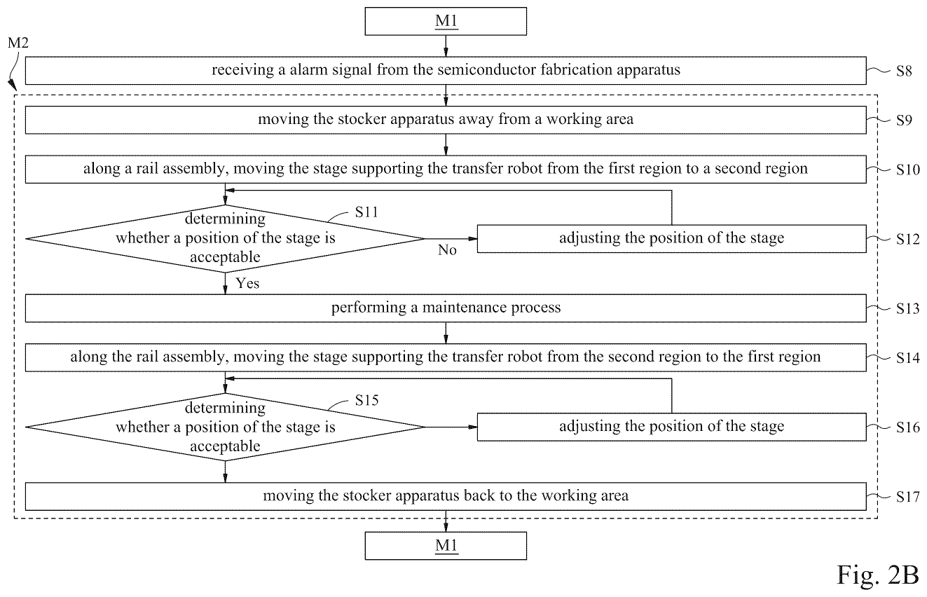

The control system 400 may include a computer-readable storage medium and a processor coupled to the computer-readable storage medium. The processor is configured to execute programming instructions stored in the computer-readable storage medium. In some embodiments, the computer-readable storage medium stores programming instructions that performs various steps of the methods in FIGS. 2A and 2B discussed later. The control system 400 controls the operations of the carrier transferring assembly 100, the stocker apparatus 200, and the semiconductor fabrication apparatus 300 by using the processor reading out and executing the program stored in the storage medium. The program may be one that has been stored in the computer-readable storage medium, or may be one that has been installed to the storage medium of the control system 400. In some embodiments, the control system 400 may include processors, central processing units (CPU), multi-processors, distributed processing systems, application specific integrated circuits (ASIC), or the like.

In some embodiments, the control system 400 may include an input device 410, and an output device 420, or a combined input/output device for enabling user interaction. The output device 420 is configured to provide information to operators. For example, the output device 420. The input device 410 comprises, for example, a keyboard, keypad, mouse, trackball, trackpad, and/or cursor direction keys for communicating information and commands to the processor of the control system 400. In the present embodiments, the input device 410 may include a button 412. An output device 420 comprises, for example, a display, a printer, a voice synthesizer, etc. for communicating information to a user.

In FIG. 1A, the load ports 310 may be arranged along a direction X in some embodiments. In some embodiments, the direction D1 of the rail assembly 124 is tilted with respect to the direction X. For example, an angle between the direction D1 of the rail assembly 124 and the direction X where the load ports 310 are arranged along is in a range from about 30 degrees to about 60 degrees. And, in some embodiments, the direction 200D of the stocker apparatus 200 intersects the direction X. For example, the direction 200D of the stocker apparatus 200 may be substantially parallel with a direction Y orthogonal to the direction X. The direction D1 is at the plane of the directions X and Y.

FIG. 1B is a schematic view of the moving mechanism 120 of the carrier transferring assembly 100 in the semiconductor processing system of FIG. 1A. Reference is made to FIGS. 1A and 1B. The moving mechanism 120 includes vehicles 121, the stage 122, the rail assembly 124, and a driving device 126. The stage 122 is configured to supporting the transfer robot 110.

The rail assembly 124 may include a pair of rails 124a and 124b spaced apart from each other. The rails 124a and 124b are linear guides extending along a direction D1, and the vehicles 121 may move (e.g., slide) on the rails 124a and 124b along the direction D1. The stage 122 is supported by the vehicles 121 and therefore can be moved along the direction Y. In the context, the vehicles 121 may be referred to as runners, sliders, slide members. The rails 124a and 124b and the vehicles 121 may be made of suitable rigid materials, such as ceramics (e.g., aluminum oxides).

The driving device 126 includes a servo motor 126a, a coupler 126b, and a driving screw 126c. The servo motor 126a may convert electrical energy into rotational motion based on input signals from the control system 400. For example, the control system 400 may send signals carrying commands, to the servo motor 126a (and its encoder) for moving the stage 122 to the first region P1 or the second region P2. The servo motor 126a uses feedback from its encoder 126e to ensure it moves accurately to the desired position or speed. The encoder 126e may include a sensor that converts the angular position of the motor shaft into an electrical signal. Thus, the encoder 126e can provide feedback about the position, speed, and direction of a servo motor 126a. This feedback allows for precise control of the movements between the first region P1 and the second region P2, enabling applications that require accuracy and reliability.

The coupler 126b connects the servo motor 126a to the driving screw 126c. It allows for the transmission of rotational motion from the servo motor 126a to the driving screw 126c. The coupler 126b can also help absorb shocks and reduce vibrations, ensuring smooth operation.

The driving screw 126c is a mechanical component used to convert rotational motion into linear motion. The driving screw 126c is mounted in a fixed position, while a nut (not shown) moves along the driving screw 126c as it rotates. The stage 122 may be attached to the nut. Stated differently, the rotation of the driving screw 126c causes the nut (and the attached stage 122) to move linearly along the direction of the driving screw 126c (e.g., the direction).

The moving mechanism 120 may further include light sensors 128a and 128b configured to detect the positions of the stage 122. For example, the light sensor 128a in the first region P1 is configured to check whether the stage 122 is in first region P1 and the light sensor 128b in the second region P2 is configured to check whether the stage 122 is in second region P2.

In some embodiments, the light sensors 128a and 128b may include a light detector that can sense and measure light intensity or the presence of light. For example, when the stage 122 is at the first region P1 and the second region P2 is absent from the stage 122, the light sensor 128a would be shielded by the stage 122 and may not detect ambient light, while the light sensor 128b would be uncovered by stage 122 and may detect ambient light. On the other hand, when the stage 122 is at the second region P2 and the first region P1 is absent from the stage 122, the light sensor 128b would be shielded by the stage 122 and may not detect ambient light, while the light sensor 128a would be uncovered by stage 122 and may detect ambient light.

In some embodiments, the light sensors 128a and 128b may include a light emitter configured to emit light (e.g., along a direction Z) and a light receiver configured to detected the light reflected by the object (e.g., the stage 122). The direction Z is orthogonal to the direction D1 (or to the plane of the directions X and Y in FIG. 1A). Thus, when the stage 122 is at the first region P1, the second region P2 is absent from the stage 122, the light emitted by the light receiver of the light sensor 128a would be detected by the light receiver of the light sensor 128a through the reflection at the backside of the stage 122, and the light emitted by the light receiver of the light sensor 128b would not be detected by the light receiver of the light sensor 128b. And, when the stage 122 is at the second region P2, the first region P1 is absent from the stage 122, the light emitted by the light receiver of the light sensor 128b would be detected by the light receiver of the light sensor 128b through the reflection at the backside of the stage 122, and the light emitted by the light receiver of the light sensor 128a would not be detected by the light receiver of the light sensor 128a.

The moving mechanism 120 may include a body/base plate BP for supporting the various components (e.g., the rails 124a and 124b, the light sensors 128a and 128b, the coupler 126b, the driving screw 126c, the like) and a cover CP shield the components (e.g., the rails 124a and 124b, the light sensors 128a and 128b, the coupler 126b, the driving screw 126c, the like) from environmental factors such as dust, moisture, and physical damage, which can extend the lifespan of the cables.

The moving mechanism 120 may further include a cable track 129 include protect the various cables and hoses that connect to the robotic system. The cables may transmit power and signals to the transfer robot 110. For example, the control system 400 may send signals carrying commands, through the cables in the cable track 129, to the transfer robot 110 for transferring the wafer carrier WC between the load ports 310 of the semiconductor fabrication apparatus 300 and the stocker apparatus 200. The cable track 129 may shield the cables from environmental factors such as dust, moisture, and physical damage, which can extend the lifespan of the cables.

An operator can control the positions of the stage 122 through the input device 410 of the control system 400 and the cables. For example, an operator may press the button 412 of the control system 400 to send the command to the driving device 126 through the cables, thereby moving the stage 122 to the second region P2. And, the operator may release button 412 of the control system 400 to send the command to the driving device 126 through the cables, thereby moving the stage 122 to the first region P1.

FIG. 1C is a side view of the semiconductor fabrication apparatus 300 of FIG. 1A. Reference is made to FIGS. 1A and 1C. The semiconductor fabrication apparatus 300 further includes an interface module 320 configured to transfer wafers W between the wafer carrier WC on the load port 310 and the semiconductor processing tool 330. For example, the interface module 320 may be an equipment front end module (EFEM). The interface module 320 may include a transfer tool 322 configured to transfer semiconductor substrates between the wafer carrier WC and the semiconductor processing tool 330. For example, the transfer tool 322 may be a robotic arm. In some implementations, the transfer tool 322 transfers wafers W between the wafer carrier WC and a staging area of the semiconductor processing tool 330.

In FIG. 1C, the exposure tool 330A of the semiconductor processing tool 330 is illustrated. For example, the exposure tool 330A may perform lithography exposing processes with the respective radiation source 332 to expose a resist layer over the wafer W. In the present embodiments, the wafer W is a semiconductor wafer, such as a silicon wafer or other type of wafer to be patterned. The wafer W is coated with a resist layer sensitive to the light from the radiation source 332 in the present embodiments. In some embodiments, the radiation source 332 generates extreme ultraviolet (EUV) light, and the resist layer is a material sensitive to the EUV light. In some embodiments, the exposure tool 330A may include various optic components (e.g., mirrors) to direct the light from the radiation source 332 onto a mask stage 334, particularly to a mask MA secured on the mask stage 334.

The exposure tool 330A may also include the mask stage 334 configured to secure the mask MA. In some embodiments, the mask stage 334 includes an electrostatic chuck (e-chuck) used to secure the mask MA. In this context, the terms mask, photomask, and reticle are used interchangeably. In the present embodiments, the exposure tool 330A uses a transmissive lithography technique, the mask MA is a transmissive mask including transparent substrate allowing the light from the radiation source 332 to transmit. In some other embodiments, the exposure tool 330A is an EUV lithography system, and the mask MA is a reflective mask including a reflective multi-layer deposited on a substrate.

The exposure tool 330A may also include an optical module 336 for imaging the pattern of the mask MA onto the wafer W secured on a substrate stage (or wafer stage) 338 of the exposure tool 330A. The optical module 336 may include reflective optics in the present embodiments. In some alternative embodiments, the optical module 336 may include refractive optics, reflective optics, or the combination thereof. Various components including those described above are integrated together inside the exposure tool 330A and are operable to perform lithography exposing processes.

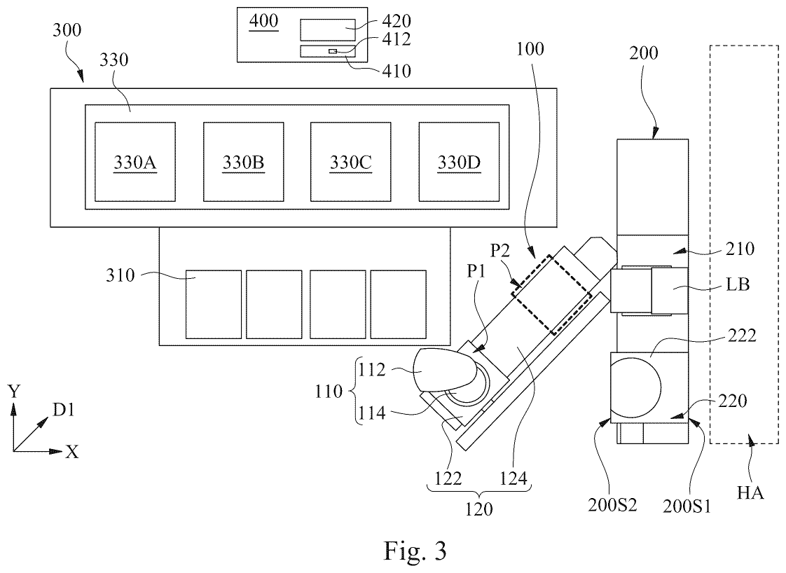

FIGS. 2A and 2B are flow charts of a method for operating a semiconductor processing system according to some embodiments of the present disclosure. FIGS. 3-13 are top views of a semiconductor processing system at operating various stages according to some embodiments of the present disclosure. The method M1 includes steps S1-S7 for handling wafers in a wafer carrier. The method M1 may be repeated for handling plural wafer carriers. The method M2 includes steps S9-S17. The method M2 is directed to a maintenance process performed after an alarm signal is sent out (as shown in step S8). It is understood that additional steps may be provided before, during, and after the steps S1-S17 shown in FIGS. 2A and 2B, and some of the steps described below can be replaced or eliminated for additional embodiments of the method. The order of the operations/processes may be interchangeable.

Reference is made to FIG. 2A and FIG. 3. The method M1 begins at step S1, where a wafer box LB is placed on a stocker apparatus 200. As aforementioned, the stocker apparatus 200 has opposite two sides 200S1 and 200S2 for manual transportation and auto transportation, respectively. For example, an empty area/alley HA, indicated by the dashed line, at the side 200S1 of the stocker apparatus 200, is connected to a main walking path, not blocking by any apparatus/machines. Thus, the operator can walk in the empty area/alley HA and approach the stocker apparatus 200 for moving the wafer box LB to the first station 210 in the stocker apparatus 200.

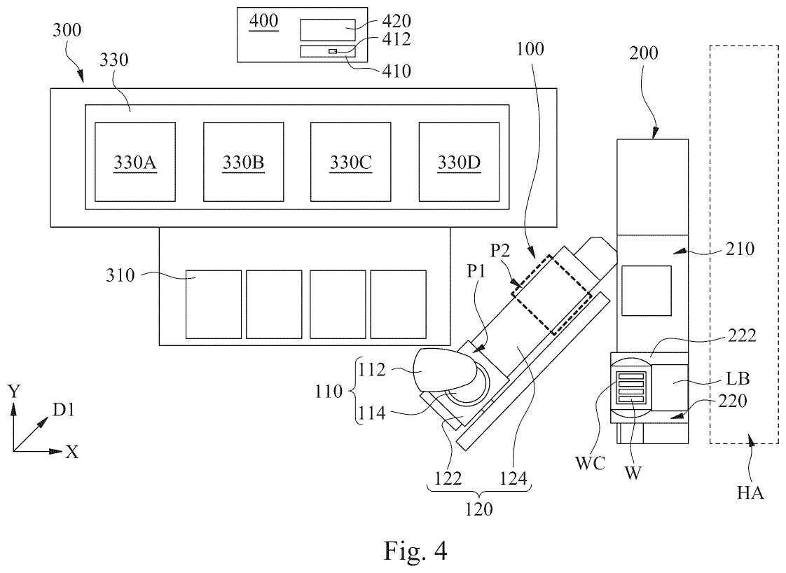

Reference is made to FIG. 2A and FIG. 4. The method M1 proceeds to step S2, where the wafer box LB is opened on the stocker apparatus 200. As aforementioned, after the wafer box LB is placed on the first station 210, the transfer robot 110 or transfer components of the stocker apparatus 200 can move the wafer box LB from the first station 210 to the second station 220. And, then, the box opening device 222 at the second station 220 can open the wafer box LB to expose the wafer carrier WC in the wafer box LB.

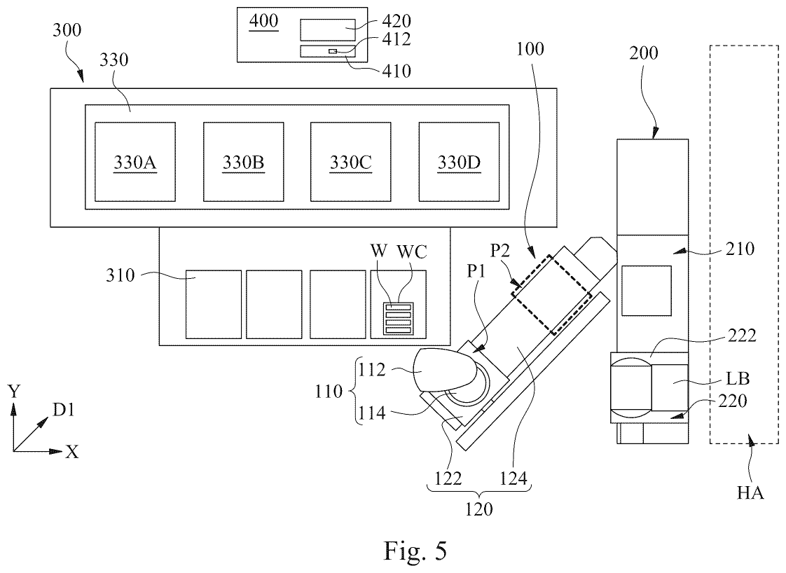

Reference is made to FIG. 2A and FIG. 5. The method M1 proceeds to step S3, where by using a transfer robot 110 at the first region P1, a wafer carrier WC in the wafer box LB is transferred onto one of the load ports 310 of the semiconductor fabrication apparatus 300. At this stage, the transfer robot 110 is supported by a stage 122 at the first region P1. In some embodiments, the transfer robot 110 has a robot arm 112 and a base 114 connected to a bottom of the robot arm 112 and supporting the robot arm 112. The robot arm 112 is capable of extending/moving the wafer carrier WC between the second station 220 and the target one of the load port 310. The base 114 may be mounted on the stage 122. For example, during the movement of the robot arm 112 of transfer robot 110, the base 114 of the transfer robot 110 remain stationary on the stage 122.

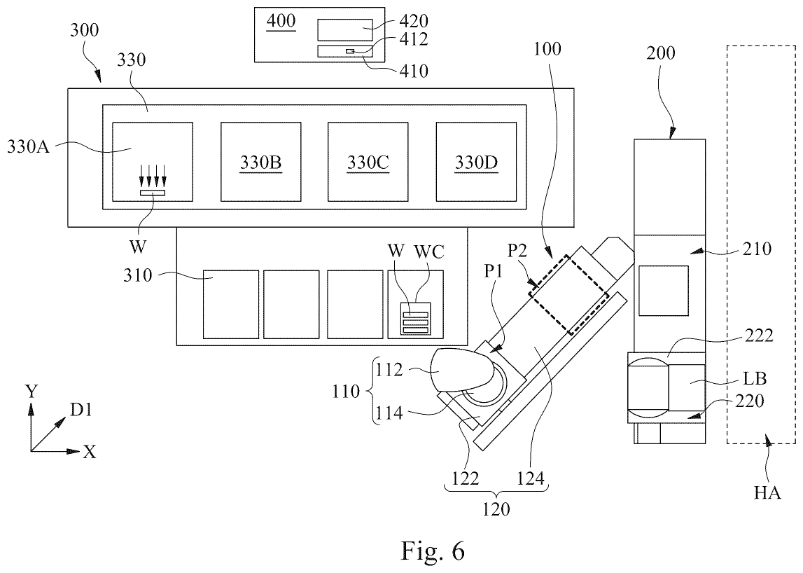

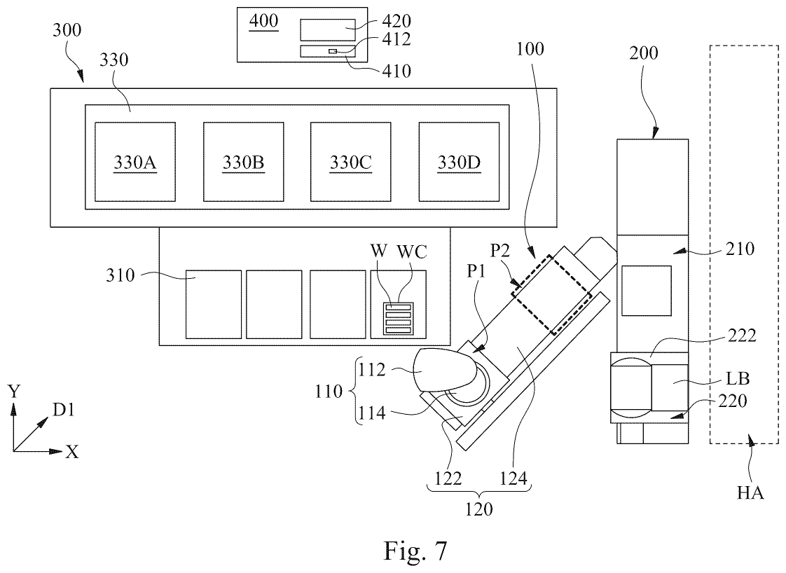

Reference is made to FIG. 2A and FIG. 6. The method M1 proceeds to step S4, where a wafer W is moved from the wafer carrier WC to a processing tool 330. Subsequently, the method M1 proceeds to step S5, where one or more semiconductor processes is performed on the wafer W in the processing tool 330. In some examples, when the wafer W is moved to an exposure tool 330A, an exposure process is performed to expose a resist on the wafer W. In some other examples, when the wafer W is moved to a deposition tool 330B, a film is deposited on the wafer W. In some other examples, when the wafer W is moved to a etch tool 330C, a material on the wafer W is etched. In some other examples, when the wafer W is moved to a baking tool 330D, the wafer W is baked. After the one or more semiconductor processes, the method M1 proceeds to step S6, where the wafer W is moved from the processing tool 330 back to the wafer carrier WC, as illustrated in FIG. 7.

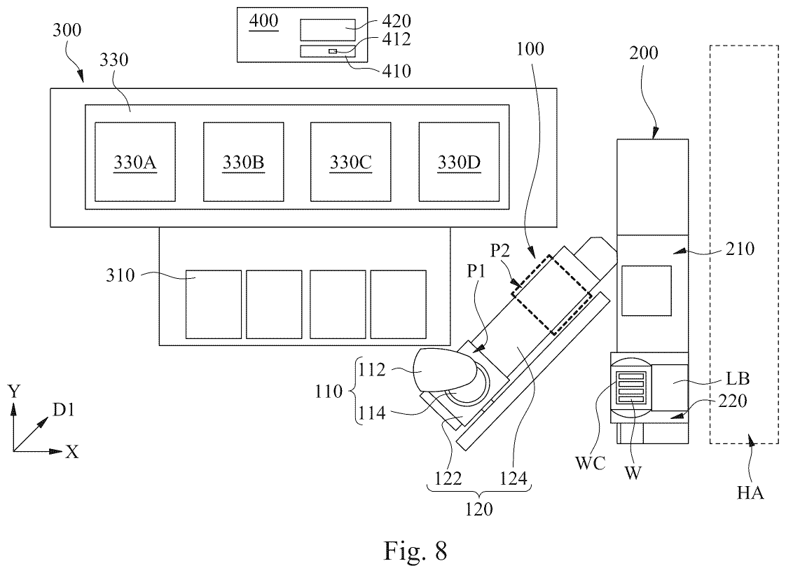

Reference is made to FIG. 2B and FIG. 8. The method M1 proceeds to step S7, where by using the transfer robot 110 at the first region P1, the wafer carrier WC on the load port 310 of the semiconductor fabrication apparatus 300 is transferred to the wafer box LB on the stocker apparatus 200. At this stage, the transfer robot 110 is supported by the stage 122 at the first region P1. During the movement of the robot arm 112 of transfer robot 110, the base 114 of the transfer robot 110 remain stationary on the stage 122.

The method M1 may be repeated for handling plural wafer carriers. After repeated method M1 for several times, the semiconductor fabrication apparatus may require a maintenance process, the like, or the combination thereof. The semiconductor fabrication apparatus may send out an alarm signal, and the operator or the control system 400 may receive the alarm signal. The operator or the control system 400 may decide to perform the method M2 directed to a maintenance process based on the alarm signal. For example, the maintenance process may include alignment, calibration, intensity inspection, gas leakage inspection, cleaning, replacement of various components, inspection of the consumed condition of various components.

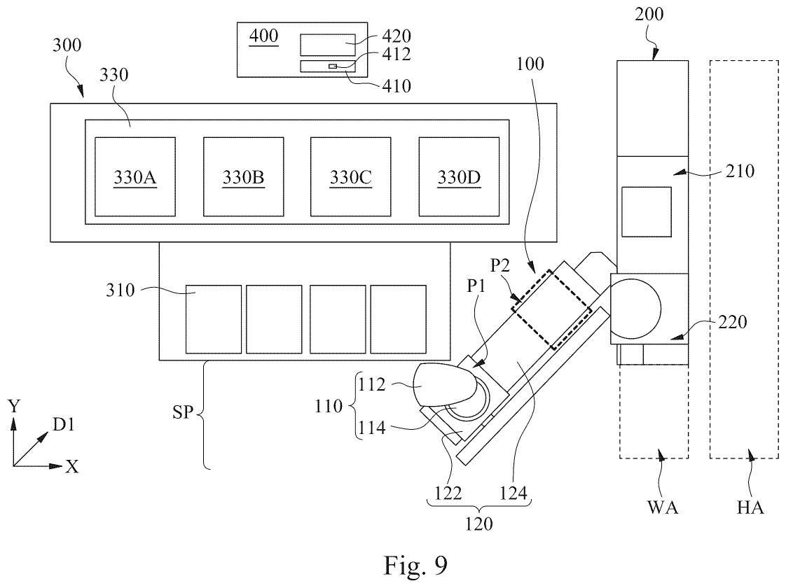

Reference is made to FIG. 2B and FIG. 9. The method M2 proceeds to step S9, the stocker apparatus 200 is moved away from a working area WA. The working area WA may be aligned with an empty space/area in front of the load ports 310 of the semiconductor fabrication apparatus 300 along the direction X. In some embodiments, the movement of the stocker apparatus 200 may be manually accomplished by operators. In some alternative embodiments, the stocker apparatus 200 may be equipped with moving mechanisms and can be automatically moved under the control of the control system 400. After the movement of the stocker apparatus 200, the working area WA is absent from the stocker apparatus 200, which leaves a temporary empty space at the working area WA.

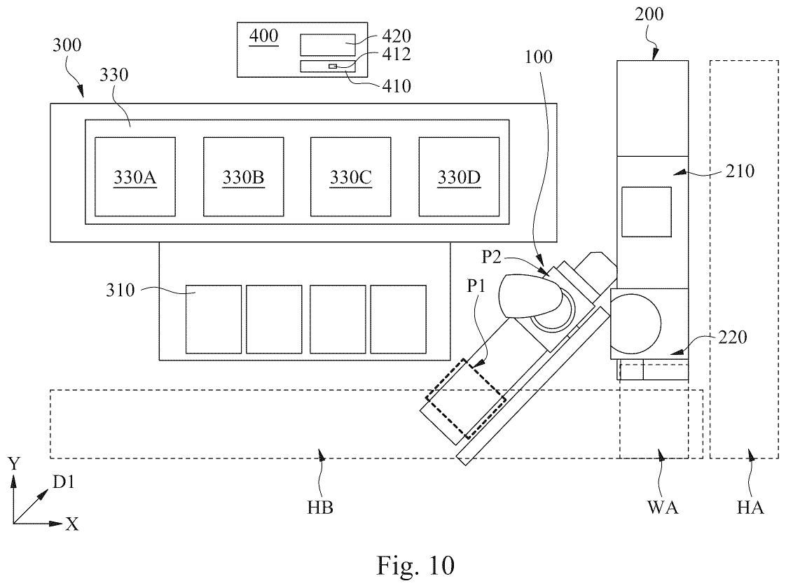

Reference is made to FIG. 2B and FIG. 10. The method M2 proceeds to step S10, the stage 122 supporting the transfer robot 110 is moved from the first region P1 to a second region P2 along a rail assembly 124. For example, the control system 400 can control the driving device 126 (referring to FIG. 1B) to move the stage 122 from the first region P1 to the second region P2.

After the movement, the first region P1 is absent from the stage 122 and the transfer robot 110, which leaves a temporary empty space at the first region P1. Thus, the empty space/area in front of the load ports 310 of the semiconductor fabrication apparatus 300, the temporary empty space at the first region P1, and the temporary empty space at the working area WA may form a temporary empty area/alley HB, indicated by the dashed line, along the direction X. The temporary empty area/alley HB is connected to the empty area/alley HA, not blocking by any apparatus/machines therebetween.

The method M2 proceeds to step S11, where a position of the stage 122 is checked and determined to be acceptable or not. The determination may include comparing the position of the stage 122 detected by the encoder 126e and the light sensors 128a and 128b in FIG. 1B with a theoretical position. If the distance/shift between the position of the stage 122 and the theoretical position is greater than a threshold value, the position of the stage 122 is determined as unacceptable, and the method M2 proceeds to step S12. At step S12, the position of the stage 122 is adjusted. For example, the control system 400 can control the driving device 126 (referring to FIG. 1B) to move the stage 122 slightly according to the comparison result. For example, the adjustment to the position of the stage 122, the method M2 goes back to the step S11. The adjustment to the position of the stage 122 at step S12 repeated until the position of the stage 122 and the theoretical position is equal to or less than a threshold value.

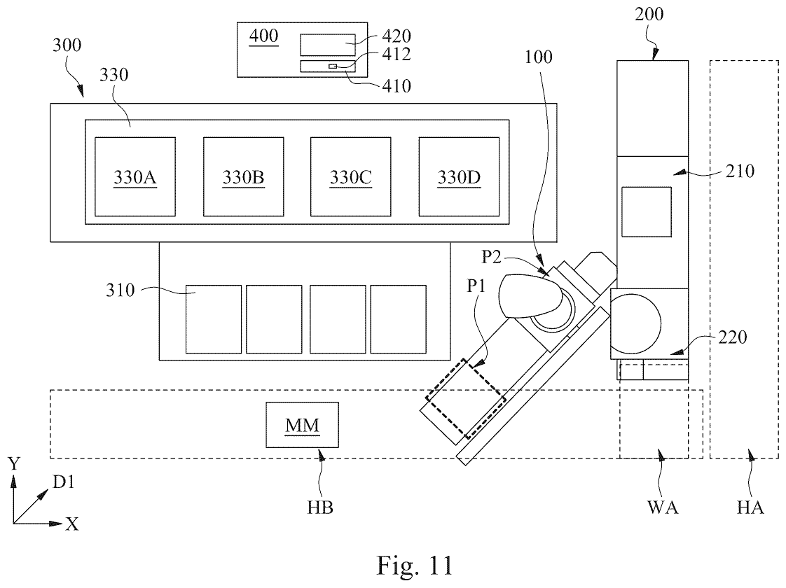

If a distance/shift between the position of the stage 122 and the theoretical position is equal to or less than a threshold value, the position of the stage 122 is determined as acceptable, and the method M2 proceeds to step S13. Reference is made to FIG. 2B and FIG. 11. At step S13, by allowing the operator to walk in the temporary empty area/alley HB and approaching the semiconductor fabrication apparatus 300, and/or moving a maintenance tool MM (e.g., a calibration tool, a cleaning tool, an inspection tool, the like, or a combination thereof) to the temporary empty area/alley HB to approach the semiconductor fabrication apparatus 300, a maintenance process is performed to the semiconductor fabrication apparatus 300. The maintenance process may include alignment, calibration, intensity inspection, gas leakage inspection, cleaning, replacement of various components, inspection of the consumed condition of various components, the like, or the combination thereof.

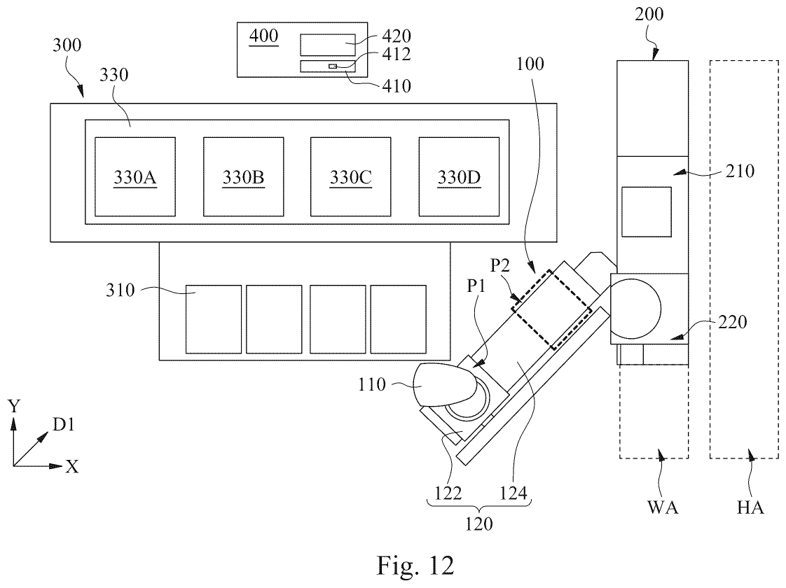

Reference is made to FIG. 2B and FIG. 12. The method M2 proceeds to step S14, after the maintenance process, the stage 122 supporting the transfer robot 110 is moved from the second position P2 to the first position P1 along the rail assembly 124. For example, the control system 400 can control the driving device 126 (referring to FIG. 1B) to move the stage 122 from the second region P2 to the first region P1. After the movement of the stage 122, the temporary empty area/alley HB in FIG. 10 is clogged, and does not allow the operator to approach the semiconductor fabrication apparatus 300.

The method M2 proceeds to step S15, where a position of the stage 122 is checked and determined to be acceptable or not. The determination may include comparing the position of the stage 122 detected by the encoder 126e and the light sensors 128a and 128b in FIG. 1B with a theoretical position. If the distance/shift between the position of the stage 122 and the theoretical position is greater than a threshold value, the position of the stage 122 is determined as unacceptable, and the method M2 proceeds to step S16. At step S16, the position of the stage 122 is adjusted. For example, the control system 400 can control the driving device 126 (referring to FIG. 1B) to move the stage 122 slightly according to the comparison result. For example, the adjustment to the position of the stage 122, the method M2 goes back to the step S15. The adjustment to the position of the stage 122 at step S16 repeated until the position of the stage 122 and the theoretical position is equal to or less than a threshold value.

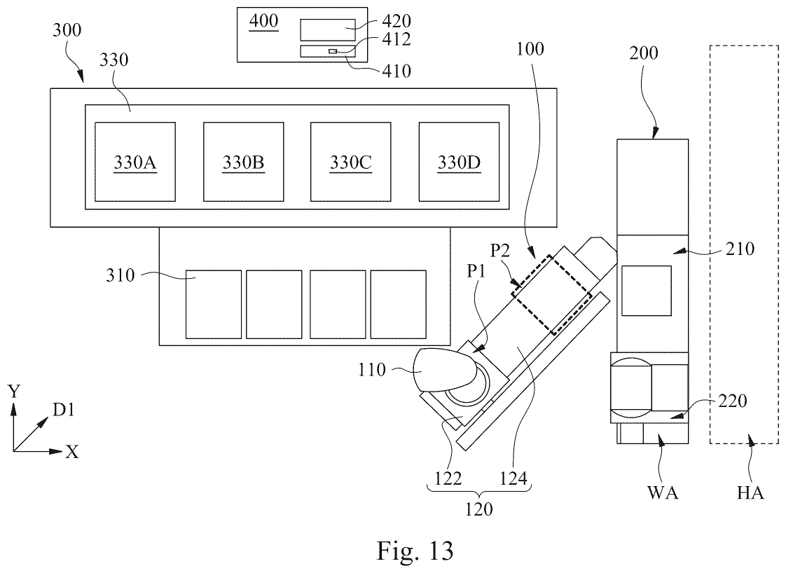

If a distance/shift between the position of the stage 122 and the theoretical position is equal to or less than a threshold value, the position of the stage 122 is determined as acceptable, and the method M2 proceeds to step S17. Reference is made to FIG. 2B and FIG. 13. At step S17, the stocker apparatus 200 is moved back to the working area WA. As aforementioned, the working area WA may be aligned with the empty space/area in front of the load ports 310 of the semiconductor fabrication apparatus 300 along the direction X. The movement of the stocker apparatus 200 may be manually accomplished by operators. In some alternative embodiments, the stocker apparatus 200 may be equipped with moving mechanisms and can be automatically moved under the control of the control system 400. After the movement of the stocker apparatus 200, the working area WA is occupied by the stocker apparatus 200.

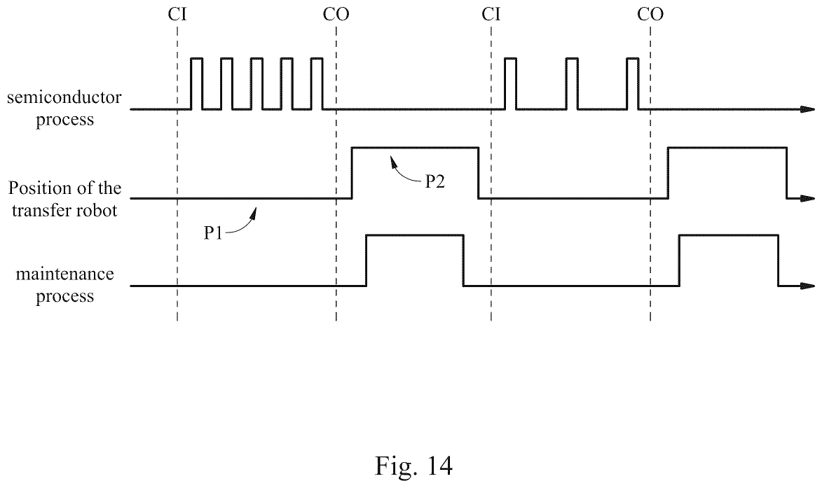

FIG. 14 shows pulses versus time for various processes when operating the semiconductor fabrication apparatus according to some embodiments of the present disclosure. In FIG. 14, dashed lines CI and CO are used to indicate the timings of wafer carrier transfer. The dashed lines CI indicate the timing when the wafer carrier WC is moved from the stocker apparatus 200 onto a load port 310 (e.g., the step S3 and FIGS. 4-5). And, the dashed lines CO indicate the timing when the wafer carrier WC is moved from the load port 310 to the stocker apparatus 200 (e.g., the step S7 and FIGS. 7-8). As shown in FIGS. 3-13, when the robot arm 112 is at the first position P1, the wafer carrier WC is transfer onto and away from the load port 310 for performing semiconductor processes on several wafers W (e.g., the step S5 and FIG. 6). And, when the robot arm 112 is at the second position P2, a maintenance process is performed (e.g., the step S13 and FIG. 11).

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a carrier transfer robot is mounted on an auto moving mechanism, such that the carrier transfer robot may be moved for creating an alley to the semiconductor process apparatus, thereby allowing a maintenance process to the semiconductor process apparatus. Another advantage is that the carrier transfer robot may be moved automatically at a fast speed. Another advantage is that the carrier transfer robot may be moved accurately to the desired position by the encoder and the light sensors. Still another advantage is that the semiconductor fabrication apparatus, the carrier transfer robot, and the stocker apparatus are arranged appropriate for saving a space in the fabrication environment.

According to some embodiments of the present disclosure, a method for operating a semiconductor processing system is provided. The method includes performing a semiconductor process by a semiconductor fabrication apparatus, wherein the semiconductor fabrication apparatus comprises a plurality of load ports arranged substantially along a first direction in a top view; moving a stage between a first region and a second region substantially along a second direction intersecting the first direction in the top view, wherein the stage supports a transfer robot, and a minimal distance from the first region to the load ports is less than a minimal distance from the second region to the load ports; transferring a wafer carrier, using the transfer robot, between a stocker apparatus and the semiconductor fabrication apparatus when the stage is at the first region; and performing a maintenance process to the semiconductor fabrication apparatus when the stage is at the second region.

According to some embodiments of the present disclosure, a method for operating a semiconductor processing system is provided. The method includes transferring a wafer carrier from a stocker apparatus to one of a plurality of load ports of a semiconductor fabrication apparatus by using a transfer robot at a working region; performing a semiconductor process by the semiconductor fabrication apparatus; after the semiconductor process, transferring the wafer carrier from said one of the load ports of the semiconductor fabrication apparatus to the stocker apparatus by using the transfer robot at the working region; and using a moving mechanism, moving the transfer robot away from the working region after transferring the wafer carrier from said one of the load ports of the semiconductor fabrication apparatus to the stocker apparatus.

According to some embodiments of the present disclosure, a semiconductor processing system includes a semiconductor fabrication apparatus, a stocker apparatus, and a carrier transferring assembly between the stocker apparatus and the semiconductor fabrication apparatus. The semiconductor fabrication apparatus includes plural load ports. The carrier transferring assembly includes a transfer robot and a moving mechanism. The transfer robot has a range of motion sufficient to transfer a wafer carrier between the semiconductor fabrication apparatus and the stocker apparatus. The moving mechanism is between the stocker apparatus and the semiconductor fabrication apparatus. The moving mechanism includes a stage and a driving device. The stage supports the transfer robot. The driving device is operable to move the stage between a first region and a second region, wherein a shortest distance from the first region to the load ports is shorter than a shortest distance from the second region to the load ports.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for operating a semiconductor processing system, comprising:
performing a semiconductor process by a semiconductor fabrication apparatus, wherein the semiconductor fabrication apparatus comprises a plurality of load ports arranged substantially along a first direction in a top view;
moving a stage between a first region and a second region substantially along a second direction intersecting the first direction in the top view, wherein the stage supports a transfer robot, and a minimal distance from the first region to the load ports is less than a minimal distance from the second region to the load ports;
transferring a wafer carrier, using the transfer robot, between a stocker apparatus and the semiconductor fabrication apparatus when the stage is at the first region; and
performing a maintenance process to the semiconductor fabrication apparatus when the stage is at the second region.

2. The method of claim 1, wherein the first region is aligned with an area in front of the load ports of the semiconductor fabrication apparatus substantially along the first direction.

3. The method of claim 1, wherein the second region is aligned with the semiconductor fabrication apparatus substantially along the first direction.

4. The method of claim 1, wherein moving the stage between the first region and the second region substantially along the second direction comprises:
moving the stage on a rail, wherein the rail extends substantially along the second direction in the top view.

5. The method of claim 1, wherein the semiconductor process is performed when the stage is at the first region.

6. The method of claim 1, further comprising:
moving the stocker apparatus away from a working area aligned with the first region substantially along the first direction in the top view, wherein the maintenance process is performed when the working area is free of the stocker apparatus.

7. The method of claim 1, further comprising open a box accommodating the wafer carrier by using a box opening device of the stocker apparatus.

8. The method of claim 7, wherein the box opening device of the stocker apparatus is aligned with the first region substantially along the first direction in the top view.

9. A method for operating a semiconductor processing system, comprising:
transferring a wafer carrier from a stocker apparatus to one of a plurality of load ports of a semiconductor fabrication apparatus by using a transfer robot at a working region;
performing a semiconductor process by the semiconductor fabrication apparatus;
after the semiconductor process, transferring the wafer carrier from said one of the load ports of the semiconductor fabrication apparatus to the stocker apparatus by using the transfer robot at the working region; and
using a moving mechanism, moving the transfer robot away from the working region after transferring the wafer carrier from said one of the load ports of the semiconductor fabrication apparatus to the stocker apparatus.

10. The method of claim 9, wherein moving the transfer robot comprises:
moving a vehicle of the moving mechanism on a rail of the moving mechanism, wherein the vehicle supports a stage, and the stage supports the transfer robot.

11. The method of claim 9, wherein moving the transfer robot comprises:
using a driving device, moving a stage supporting the transfer robot on a signal from a control system.

12. The method of claim 11, further comprising:
using a light sensor, detecting a position of the stage after moving the stage.

13. The method of claim 9, further comprising:
performing a maintenance process when the transfer robot is away from the working region.

14. The method of claim 13, wherein performing the maintenance process comprises:
moving a maintenance tool to an area in front of the load ports of the semiconductor fabrication apparatus.

15. A semiconductor processing system, comprising:
a semiconductor fabrication apparatus comprising a plurality of load ports;
a stocker apparatus; and
a carrier transferring assembly between the stocker apparatus and the semiconductor fabrication apparatus, wherein the carrier transferring assembly comprises:
a transfer robot having a range of motion sufficient to transfer a wafer carrier between the semiconductor fabrication apparatus and the stocker apparatus; and
a moving mechanism, comprising:
a stage supporting the transfer robot; and
a driving device operable to move the stage between a first region and a second region, wherein a shortest distance from the first region to the load ports is shorter than a shortest distance from the second region to the load ports.

16. The semiconductor processing system of claim 15, wherein the moving mechanism further comprises:
a rail; and
a vehicle supporting the stage and configured to move on the rail.

17. The semiconductor processing system of claim 15, wherein the load ports of the semiconductor fabrication apparatus are arranged substantially along a first direction in a top view, and the first region is aligned with an area in front of the load ports of the semiconductor fabrication apparatus substantially along the first direction.

18. The semiconductor processing system of claim 15, wherein the load ports of the semiconductor fabrication apparatus are arranged substantially along a first direction in a top view, and the moving mechanism comprises a rail extending along a second direction between the first region and the second region, and the second direction intersects the first direction in the top view.

19. The semiconductor processing system of claim 15, wherein the moving mechanism further comprises a light sensor having a range of detection sufficient to detect a position of the stage.

20. The semiconductor processing system of claim 15, wherein the stocker apparatus comprises a box opening device operable to open a box accommodating the wafer carrier.
